(19) United States
(12) Patent Application Publication
(10) Pub. No.: US 2026/0026059 A1
(43) Pub. Date: Jan. 22, 2026

(54) SEMICONDUCTOR DEVICES AND METHODS FOR FABRICATION THEREOF

(71) Applicant: TAIWAN SEMICONDUCTOR MANUFACTURING COMPANY, LTD., Hsinchu (TW)

(72) Inventors: Chen-Han LU, Hsinchu (TW); Jin CAI, Hsinchu (TW); Chih-Hao WANG, Hsinchu (TW); Kuo-Cheng CHIANG, Hsinchu (TW); Sheng-Kai SU, Hsinchu (TW); Chien-Hong CHEN, Hsinchu (TW)

(21) Appl. No.: 18/978,179

(22) Filed: Dec. 12, 2024

Related U.S. Application Data
(60) Provisional application No. 63/673,741, filed on Jul. 21, 2024.

(51) Int. Cl. H10D 62/40; H10D 30/00; H10D 30/01; H10D 62/53; H10D 64/01

(52) U.S. Cl. CPC H10D 62/405; H10D 30/0191; H10D 30/502; H10D 62/53; H10D 64/017

(57) ABSTRACT

Embodiments of the present disclosure provide a GAA device fabricated from a substrate having a (551)<110> top surface. Selecting the (551)/<110> substrate enables channel height scaling with improved hole mobility and without sacrificing electron mobility.

### CROSS-REFERENCE TO RELATED APPLICATIONS

This application claims priority to the U.S. Provisional Patent Application Ser. No. 63/673,741 filed Jul. 21, 2024, which is incorporated by reference in its entirety.

### BACKGROUND

The semiconductor industry has experienced continuous rapid growth due to constant improvements in the integration density of various electronic components. For the most part, this improvement in integration density has come from repeated reductions in minimum feature size, allowing more components to be integrated into a given chip area. As minimum feature size reduces, the trade-off between hole and electron mobility in the channel regions become a challenge which affects device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor device according to embodiments of the present disclosure.

FIGS. 2, 2A, 3, 4, 4A, and 5-10 schematically illustrate various stages of manufacturing a semiconductor device according to embodiments of the present disclosure.

FIGS. 11A, 11B, 11C, 11D, and 11E illustrate gate areas of GAA devices according to embodiments of the present disclosure.

FIGS. 12A-12B illustrate electron mobility of GAA devices according to embodiments of the present disclosure.

FIG. 13 schematically illustrate a semiconductor device according to embodiments of the present disclosure.

FIG. 14 schematically illustrate a semiconductor device according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 64 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Horizontally stacked GAA nanosheet channel structure offers excellent short channel control and increased effective channel width (Weff) per footprint. Further nanosheet height scaling with performance improvement is in high demand for the continuously scaling technology nodes.

In current technology, the GAA nanosheet channels are formed on (100) substrate surface orientation with channels along <110> direction (hereafter referred to as (100)/<110> channel) or on (110) substrate surface orientation with channel along <110> direction (hereafter referred to as (110)/<110> channels). As the channel height reduces, (100)/<110> channels suffer significant hole mobility loss while gain slightly on electron mobility. The (110)/<110> channels on the other hand, suffer some degree of electron mobility loss with channel height reduction while gain some in hole mobility. Therefore, to further scaling down channel heights under the current technology inevitably faces the trade-off between hole mobility loss or electron mobility loss.

Additionally, it has been observed that various other factors, such as surface roughness scattering (SRS), remote phonon scattering (RPS), acoustic deformation potential (ADP), and remote coulomb scattering (RCS), also contribute to the electron mobility loss, particularly as the channel width is scaling down. Among these factors, surface roughness scattering factor dominates the performing of electron mobility for (110)/<110>.

Embodiments of the present disclosure provide a thin channel nanosheet device and method for forming the device by selecting (551)/<110> substrate as starting material. The (551) surface is tilted 8 degrees from the (110) surface towards (100) surface and has similar band structure and other scatterings factors as the (110) surface. As a result, the (551) surface provides gain the same high hole mobility as (110) surface as sheet height scaling down. Additionally, the (551)/<110> channels exhibit (100)/<110> channel like electron mobility, i.e., without suffering electron mobility loss with channel height scaling down.

Therefore, GAA devices with (551)/<110> channels according to the present disclosure provide improved hole mobility as the (110)/<110> channels without suffering electron mobility.

Additionally, (551) silicon surface has potential to attain lower surface roughness. In some embodiments, a surface roughness treatment is performed to (551) surface, thereby, to reduce SRS factor and improve electron mobility. In conclusion, (551)/<110> channels according to the present disclosure provide gain in the hole mobility without sacrificing the electron mobility as channel height reduces.

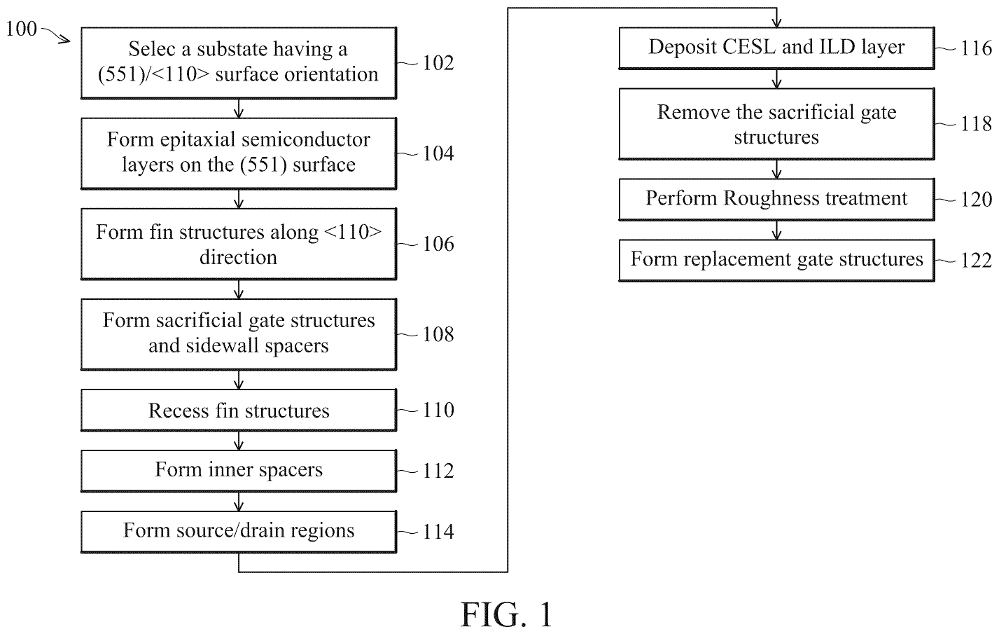

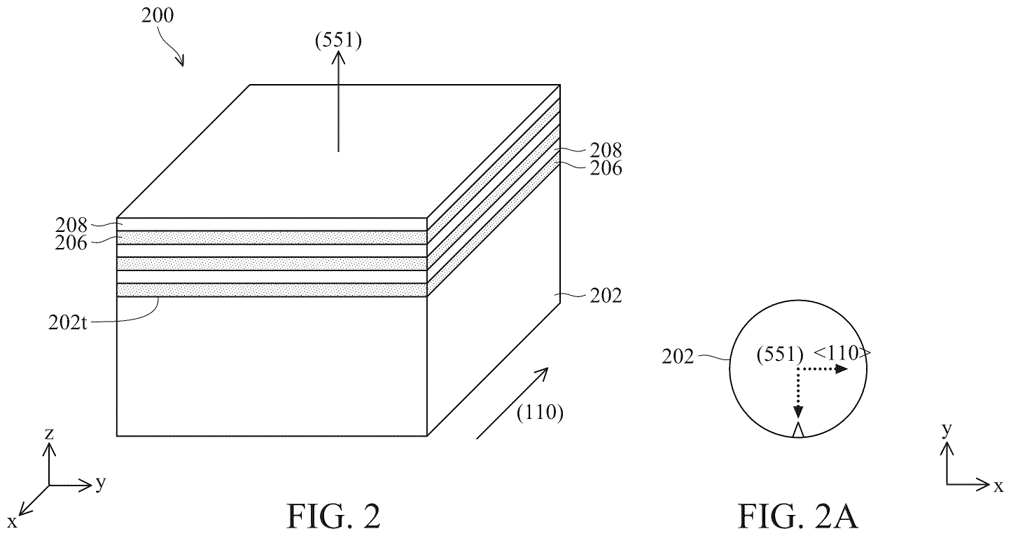

FIG. 1 is a flow chart of a method 100 for manufacturing of a semiconductor device according to embodiments of the present disclosure. FIGS. 2, 2A, 3, 4, 3A, and 5-10 schematically illustrate various stages of manufacturing an exemplary semiconductor device 200 according to embodiments of the present disclosure. Particularly, the semiconductor device 200 may be manufactured according to the method 100 of FIG. 1.

At operation 102 of the method 100, a substrate 202 having a (551) surface orientation is selected for forming the semiconductor device 200 thereon. FIG. 2A is a schematic plan view of the substrate 202 according to the present disclosure. A top surface 202t of the substrate 202 is a (551) oriented facet surface. Particularly, the (511) surface is 8 degrees tilted toward <100> direction from (110) surface. As shown in FIGS. 2 and 2A, the substrate 202 has a <110> direction along the x-direction.

In some embodiments, the substrate 202 may include a single crystalline semiconductor material such as, but not limited to Si, Ge, SiGe, GaAs, InSb, GaP, GaSb, InAlAs, InGaAs, GaSbP, GaAsSb, and InP.

The substrate 202 may include various doping configurations depending on circuit design. For example, the substrate 202 may include p-doped regions or p-well and an n-doped regions or n-wells. One or more n-type devices, such as nFETs, are to be formed over and/or within p-well. One or more p-type devices, such as pFETs, are to be formed over and/or within n-well.

At operation 104 of the method 100, a semiconductor stack including alternating first semiconductor layers 206 and second semiconductor layers 208 the substrate 202 to facilitate formation of nanosheet channels in a multi-gate n-type device, such as nanosheet channel FETs. The first semiconductor layers 206 and the second semiconductor layers 208 may be epitaxially grown from the top surface 202b of the substrate 202. Because the nature of epitaxial growth, the first and second semiconductor layers 206, 208 also have a (551) surface orientation.

The first semiconductor layers 206 and second semiconductor layers 208 have different compositions. In some embodiments, the two semiconductor layers 206 and 208 provide for different oxidation rates and/or different etch selectivity. In later fabrication stages, portions of the second semiconductor layers 208 form nanosheet channels in a multi-gate device. Three first semiconductor layers 206 and three second semiconductor layers 208 are alternately arranged as illustrated in FIG. 2 as an example. More or less semiconductor layers 206 and 208 may be included depending on the desired number of channels in the semiconductor device to be formed. In some embodiments, the number of semiconductor layers 206 and 208 is between 1 and 10.

For n-type device or nFETs, the first semiconductor layer 206 may include silicon germanium (SiGe). The first semiconductor layer 206 may be a SiGe layer including more than 25% Ge in molar ratio. For example, the first semiconductor layer 206 may be a SiGe layer including Ge in a molar ration in a range between 25% and 50%. For n-type device or nFETs, the second semiconductor layer 208 may include silicon. In some embodiments, the second semiconductor layer 208 is a silicon layer.

For p-type device or pFETs, the first semiconductor layer 206 may include silicon germanium (SiGe). The first semiconductor layer 206 may be a SiGe layer including more than 25% Ge in molar ratio. For example, the first semiconductor layer 206 may be a SiGe layer including Ge in a molar ration in a range between 25% and 50%. For p-type device or pFETs, the second semiconductor layer 208 may include silicon, Ge, a compound semiconductor such as SiC, GeAs, GaP, InP, InAs, and/or InSb, an alloy semiconductor such as SiGe, GaAsP, AllnAs, AlGaAs, InGaAs, GaInP, and/or GaInAsP, or combinations thereof. In some embodiments, the second semiconductor layer 208 is a silicon layer.

The semiconductor layers 206, 208 may be formed by a molecular beam epitaxy (MBE) process, a metalorganic chemical vapor deposition (MOCVD) process, and/or other suitable epitaxial growth processes. The semiconductor stacks for n-type devices and p-type devices may be formed separately using patterning technology.

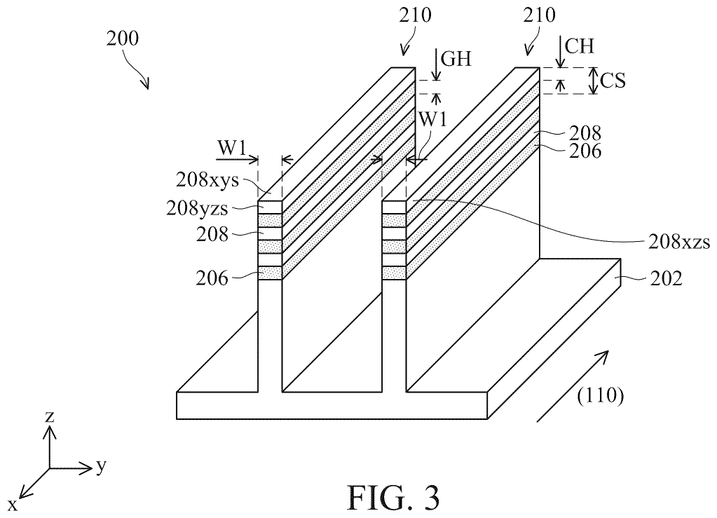

At operation 106 of the methods 100, fin structures 210 are then formed from etching the semiconductor stack and a portion of the substrate 202 underneath respectively as in FIG. 3, which is a schematic perspective view of the semiconductor device 200. As shown in FIG. 3, the fin structures 210 are formed along the x-direction. In other words, the fin structures 210 are formed along the <110> direction.

As shown in FIG. 3, after formation of the fin structures 210, each of the semiconductor layers 208 has two horizontal channel surfaces 208xys paralleled to the top surface 202t of the substrate 202. The horizontal channel surfaces 208xys have (551) surface orientation. Each of the semiconductor layer 208 also has two vertical channel surfaces 208xzs along the x-direction. At ends of the fin structures 210, the semiconductor layer 208 has two channel end surfaces 208yzs. In some embodiments, the channel end surfaces 208yzs have (110) surface orientation.

In some embodiments, each of the fin structure 210 has a width W1 along the y-direction. The width W1 may be selected according to circuit design. In some embodiments, the width W1 may be in a range between about 10 nm to about 200 nm. Portions of the semiconductor layers 208 function as channel regions connected between source/drain features in the semiconductor device to be formed. Each semiconductor layer 208 may have a channel height CH along the z-direction. In some embodiments, the channel height CH is in a range between about 2 nm and about 10 nm. The semiconductor layers 206 serve to define a vertical distance between adjacent channel regions formed by the semiconductor layers 208 for a subsequently formed device. Each semiconductor layer 206 may have a gate height GH along the z-direction. In some embodiments, the gate height GH of the semiconductor layers 206 is equal to or greater than the channel height CH of the semiconductor layer 208. In some embodiments, the gate height GH is in a range between about 2 nm and about 10 nm. A channel spacing CS, combined distance of the gate height GH and the channel height CH, may be in a range between 4 nm and 20 nm. It should be noted that the channel height CH will reduce and the gate height GH will increase as portions of the semiconductor layers 206 may be removed with the semiconductor layers 208 during the subsequent replacement gate process. However, the channel spacing CS remain substantially unchanged.

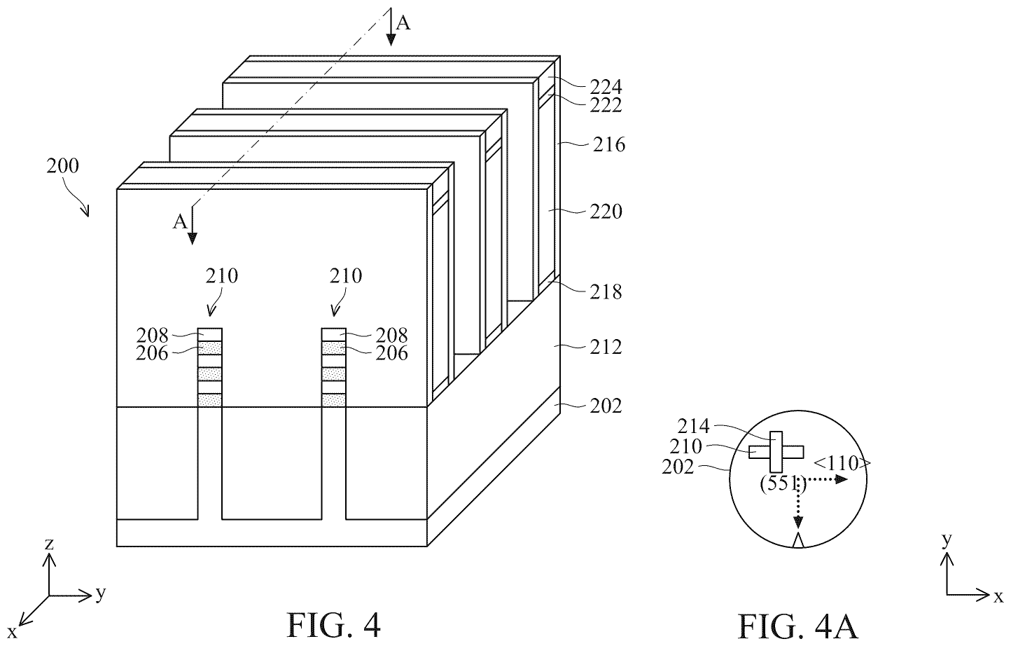

After formation of the fin structures, an isolation layer 212 is formed as shown in FIG. 4, which is a schematic view of the semiconductor device 200. The isolation layer 212 is filled in the trenches between the fin structures 210 and then etched back to below the semiconductor stacks of the fin structures 210. The isolation layer 212 may be formed by a high density plasma chemical vapor deposition (HDP-CVD), a flowable CVD (FCVD), or other suitable deposition process. In some embodiments, the isolation layer 212 may include silicon oxide, silicon nitride, silicon oxynitride, fluorine-doped silicate glass (FSG), a low-k dielectric, combinations thereof. In some embodiments, the isolation layer 212 is formed to cover the fin structures 210 by a suitable deposition process to fill the trenches between the fin structures 210, and then recess etched using a suitable anisotropic etching process to expose the active portions of the fin structures 210.

At operation 108, sacrificial gate structures 214 are formed over the isolation layer 212 and over the exposed portions of the fin structures 210 as shown in FIG. 4, which is a schematic perspective view of the semiconductor device 200. The sacrificial gate structures 214 are formed over portions of the fin structures 210 which are to be channel regions. FIG. 4A is a schematic plane view of the substrate 202 showing the direction of the fin structures 210 and the sacrificial gate structures 214. As shown in FIG. 4A, the fin structures 210 is formed along the <110> direction and the sacrificial gate structures 214 is perpendicular to the fin structures 210.

The sacrificial gate structures 214 may include a sacrificial gate dielectric layer 218, a sacrificial gate electrode layer 220, a pad layer 222, and a mask layer 224.

The sacrificial gate dielectric layer 218 may be formed conformally over the fin structures 210a, 210b, and the isolation layer 212. In some embodiments, the sacrificial gate dielectric layer 218 may be deposited by a CVD process, a sub-atmospheric CVD (SACVD) process, a FCVD process, an ALD process, a PVD process, or other suitable process. The sacrificial gate dielectric layer 218 may include one or more layers of dielectric material, such as SiO₂, SiN, a high-k dielectric material, and/or other suitable dielectric material.

The sacrificial gate electrode layer 220 may be blanket deposited on the over the sacrificial gate dielectric layer 218. The sacrificial gate electrode layer 220 includes silicon such as polycrystalline silicon or amorphous silicon. The thickness of the sacrificial gate electrode layer is in a range between about 42 nm and about 200 nm. In some embodiments, the sacrificial gate electrode layer 220 is subjected to a planarization operation. The sacrificial gate electrode layer 220 may be deposited using CVD, including LPCVD and PECVD, PVD, ALD, or other suitable process.

Subsequently, the pad layer 222 and the mask layer 224 are formed over the sacrificial gate electrode layer 220. The pad layer 222 may include silicon nitride. The mask layer 224 may include silicon oxide. Next, a patterning operation is performed on the mask layer 224, the pad layer 222, the sacrificial gate electrode layer 220 and the sacrificial gate dielectric layer 218 to form the sacrificial gate structures 214.

Gate sidewall spacers 216 are then formed on sidewalls of the sacrificial gate structures 214, The gate sidewall spacers 216 are formed on sidewalls of each sacrificial gate structures 214 as shown in FIG. 4. The gate sidewall spacers 216 is formed by a blanket deposition of one or more layers of insulating material. The insulation material may be deposited by any suitable deposition method. In some embodiments, the gate sidewall spacers 216 may be formed by ALD or CVD. In some embodiments, the insulating material of the gate sidewall spacers 216 may include one or more dielectric material. In some embodiments, the insulating material of the gate sidewall spacers 216 may include dielectric material selected from silicon oxide, silicon nitride, such as Si₃N₄, carbon doped silicon oxide, nitrogen doped silicon oxide, porous silicon oxide, or combination thereof.

The gate sidewall spacers 216 has a thickness in a range between about 3 nm and about 12 nm along the x-direction and cover a portion of the fin structures 210. In some embodiments, the gate sidewall spacers 216 is subjected to anisotropic etching to remove the gate sidewall spacers 216 from horizontal surfaces, such as the top surface of the mask layer 224 and the top surface of the isolation layer 212. In other embodiments, the gate sidewall spacers 216 on the horizontal surfaces may be removed during fin structure etch back in operation 108 discussed below.

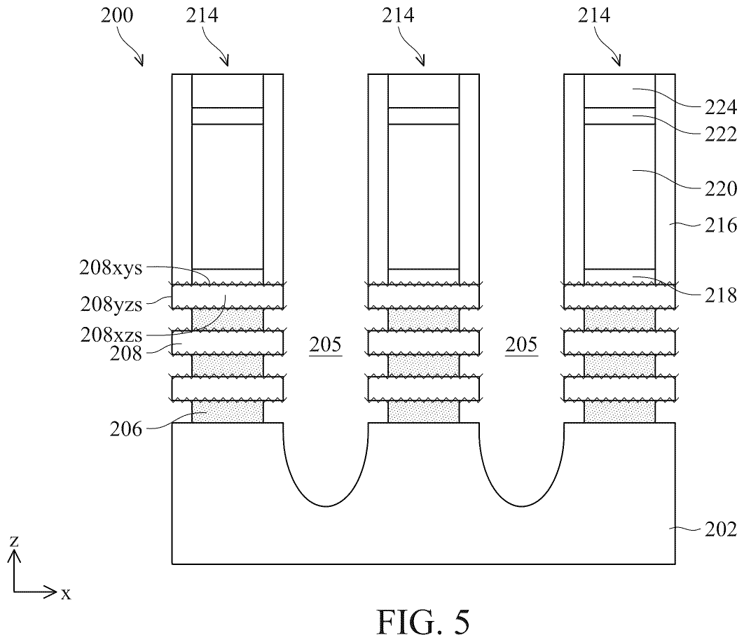

At operation 110, the fin structures 210 not covered by the sacrificial gate structures 214 are etched back, as shown in FIG. 5, which is a cross sectional view of the semiconductor device 200 along the line A-A in FIG. 4 respectively. The fin structures 210 not covered by the sacrificial gate structures 214 and the gate sidewall spacers 216 are etched to expose well portions of each fin structure 210 and form source/drain cavities 205. In some embodiments, suitable dry etching and/or wet etching may be used to remove the semiconductor layers 206, 208 together or separately.

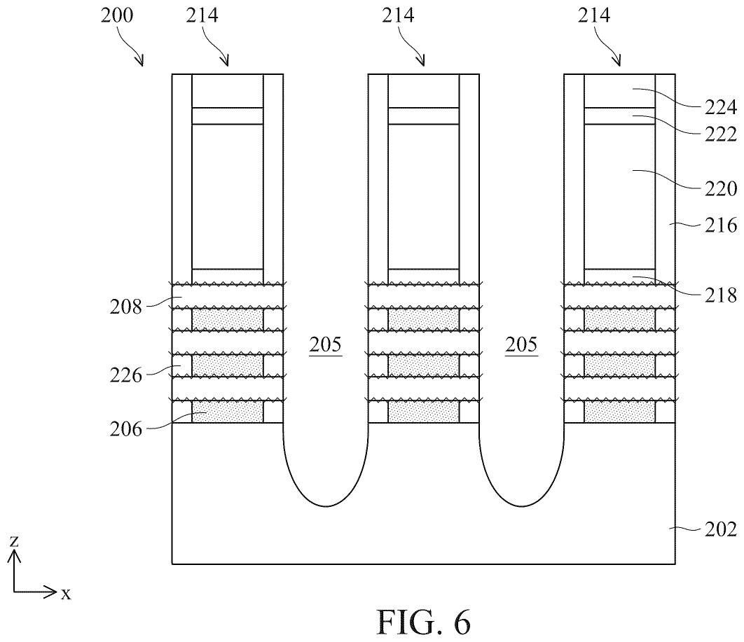

At operation 112, inner spacers 226 are formed as shown in FIGS. 5-6. To form the inner spacers 226, the semiconductor layers 206 exposed to the source/drain cavities 205 are partially etched from the semiconductor layers 208 along the horizontal direction, or x-direction, to form inner spacer cavities under the gate sidewall spacers 216, as shown in FIG. 5. In some embodiments, the semiconductor layers 206 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After forming the inner spacer cavities, the inner spacers 226 are formed in the inner spacer cavities by conformally deposit and then partially remove an insulating layer by an anisotropic etching process. The insulating layer can be formed by ALD or any other suitable method. The subsequent etch process removes most of the insulating layer except inside the cavities, resulting in the inner spacers 226. In some embodiments, the inner spacers 226 may include one or more dielectric material. In some embodiments, the inner spacers 226 may include dielectric materials, such as SiO2, SiON, SiOC, or SiOCN based dielectric materials, air gaps, or combination thereof.

The inner spacers 226 and the gate sidewall spacers 216 may be formed from the same material or different material to achieve desired performance. In some embodiments, the inner spacers 226 may have a dielectric constant k lower than that of the gate sidewall spacer 216 to obtain a desired performance, for example, a low capacitance. In some embodiments, the inner spacers 226 may have a dielectric constant k higher than that of the gate sidewall spacer 216 to obtain a desired performance, for example, an increased device reliability.

The inner spacers 226 has a thickness a range between about 3 nm and about 12 nm along the x-direction. In some embodiments, the thickness of the inner spacers 226 is substantially similar to the thickness of the gate sidewall spacers 216.

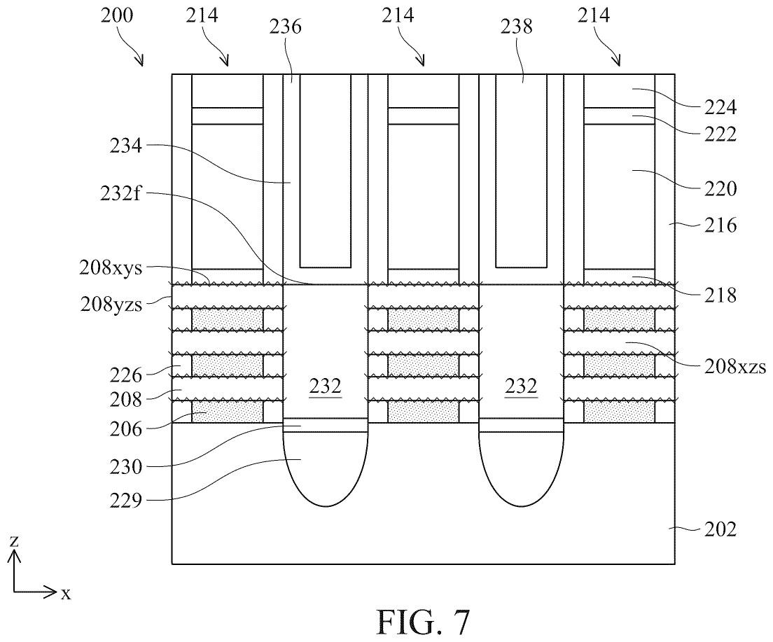

At operation 114, epitaxial source/drain regions 232 are formed as shown in FIG. 7. In some embodiments, a bottom epitaxial layer 229 may be formed at a bottom of the source/drain cavities 205. The bottom epitaxial layer 229 may be an epitaxial semiconductor layer grown from the substrate 202, therefore, has the same crystalline orientation as the substrate 202. The bottom epitaxial layer 229 may be a transitional layer between the crystalline structures of the semiconductor substrate 202 and the epitaxial source/drain region 232. In some embodiments, the bottom epitaxial layer 229 may be used as an alignment feature for forming backside source/drain contacts.

A bottom isolation layer 230 may be formed on the bottom epitaxial layer 229. The bottom isolation layer 230 may include one or more dielectric material. The bottom isolation layer 230 may be formed by a deposition process followed by an etching process. The bottom isolation layer 230 may prevent leakage between the source/drain regions 232 and the mesa region under the sacrificial gate structures 214.

The epitaxial source/drain regions 232 may be epitaxially grown in the source/drain cavities 205 from exposed surfaces such as the semiconductor layers 208 and the substrate 202. The epitaxial source/drain regions 232 for N-type devices and the epitaxial source/drain regions 232 for the P-type devices are usually formed separately using patterning technology.

The epitaxial source/drain regions 232 for n-type devices may include one or more layers of Si, SiP, SiC and SiCP. The epitaxial source/drain regions 232 also include N-type dopants, such as phosphorus (P), arsenic (As), etc. In some embodiments, the epitaxial source/drain regions 232 may be a Si layer includes phosphorus (P) dopants. The epitaxial source/drain regions 232 for the p-type device may include one or more layers of Si, SiGe, Ge with p-type dopants, such as boron (B). In some embodiments, the epitaxial source/drain regions 232 may be SiGe material including boron as dopant.

The epitaxial source/drain regions 232 are grown from the channel end surfaces 208yzs, as a result, a portion of sidewall 232s of the source/drain regions have the same surface orientation as the channel end surfaces 208yzs. In some embodiments, portions of the sidewall 232s in contact with the semiconductor layers 208 have a (110) surface orientation.

At operation 116, a contact etch stop layer (CESL) 236 and an interlayer dielectric (ILD) layer 238 are conformally formed over the semiconductor substrate, as shown in FIG. 7.

The CESL 236 may by uniformly formed over exposed surfaces of the semiconductor device 200. The CESL 236 formed on exposed facet surfaces 232f of the epitaxial source/drain regions 232, exposed surfaces of the gate sidewall spacers 216, and exposed surfaces of the isolation layer 212. The CESL 236 acts as an etch stop to provide protection to the source/drain regions 232 during formation of source/drain contact features. The CESL 236 may include Si₃N₄, SiON, SiCN or any other suitable material, and may be formed by CVD, PVD, or ALD.

The ILD layer 238 is formed over the CESL 236. The materials for the ILD layer 238 include compounds comprising Si, O, C, and/or H, such as silicon oxide, SiCOH and SiOC. Organic materials, such as polymers, may be used for the ILD layer 238. In some embodiments, the ILD layer 238 may be formed by flowable CVD (FCV). The ILD layer 238 protects the epitaxial source/drain regions 232 during the removal of the sacrificial gate structures 214. A planarization process, such a CMP process, may be performed after the deposition of the material for the ILD layer 238 to expose to the sacrificial gate structures 214 for the subsequent processing.

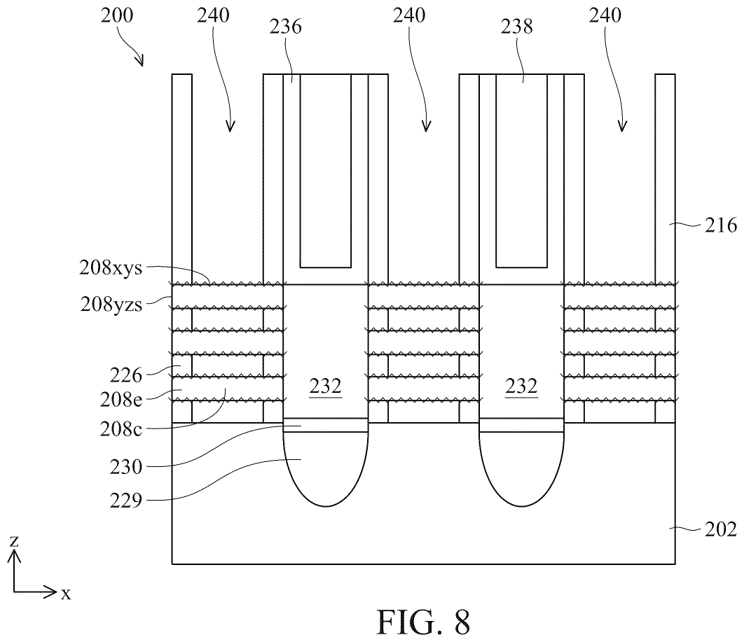

At operation 118, the sacrificial gate structures 214 and the semiconductor layer 206 to expose the semiconductor layers 208 as shown in FIG. 8. The sacrificial gate dielectric layer 218 and the sacrificial gate electrode layer 220 are removed using dry etching, wet etching, or a combination. The semiconductor layers 206 are exposed and subsequently removed resulting in gate cavities 240 surrounding nanosheets of the semiconductor layers 208. As shown in FIG. 8, a central portion 208c of each of the semiconductor layers 208 is exposed to the gate cavity 240 while end portions 208e of each of the semiconductor layers 208 are covered by the inner spacers 226 and the gate sidewall spacers 216.

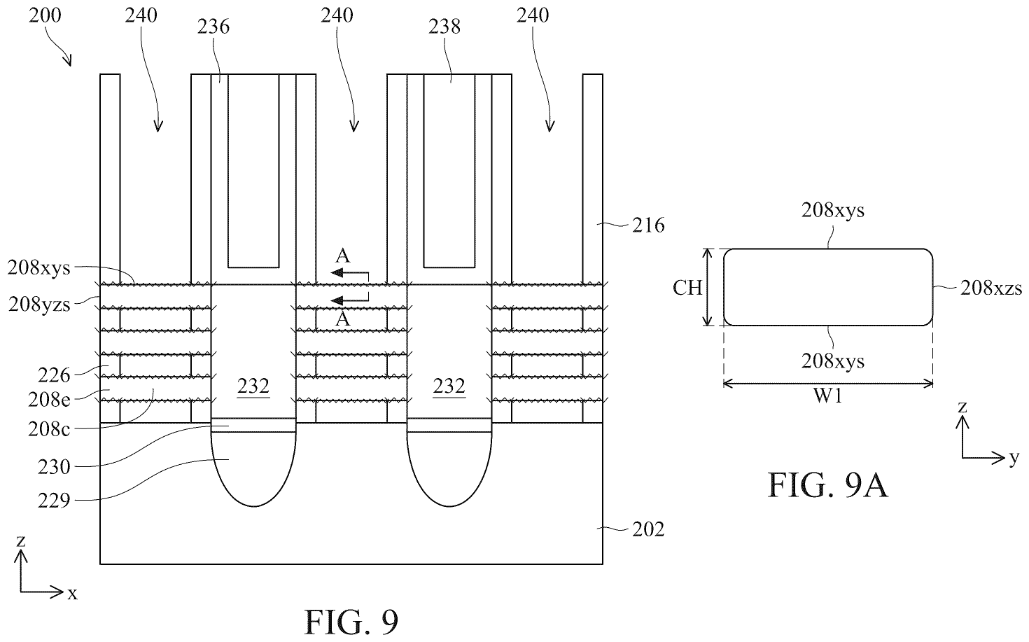

At operation 120, a roughness treatment process is performed to reduce surface roughness of the central portions of the semiconductor layers 208, as shown in FIG. 9.

In some embodiments, the roughness treatment process may be performed by treating the semiconductor device 200 in a treatment gas. In some embodiments, the roughness treatment process may be performed by Xe/H₂ plasma, H₂ anneal, H radical, or the like.

The roughness treatment process improves the surface flatness of the exposed portion of the semiconductor layers 208, i.e. the center portion 208c of the semiconductor layers 208. FIG. 9A is a partial enlarged cross sectional view of the semiconductor layer 208 exposed to the gate cavity 240. As shown in FIG. 9A, the horizontal channel surfaces 208xys and the vertical channel surfaces 208xzs are exposed to the process chemistry.

As discussed above, the horizontal channel surfaces 208xys have a (551) surface orientation, which is stable in alkali solutions and is advantageous in preserving surface flatness and reducing surface roughness. In some embodiments, after the roughness treatment, the horizontal channel surfaces 208xys of the central portion 208c of the semiconductor layers 208 may achieve a roughness Δᵣₘₛ less than about 3.0 A, for example about 1.1 A while the unexposed end portions 208e have a roughness Δᵣₘₛ about 5.2 A.

The vertical channel surfaces 208xzs may have a (1 1 10) surface. The roughness treatment also improves the flatness of the vertical channel surfaces 208xzs, but in lesser degree than the horizontal channel surfaces 208xys. In some embodiments, after the roughness treatment, the vertical channel surfaces 208xzs of the central portion 208c of the semiconductor layers 208 may achieve a roughness Δᵣₘₛ less than about 5.0 A, for example in a range between about 4.2 A and about 4.8 A, while the unexposed end portions 208e have a roughness Δᵣₘₛ in a range between about 5.0 A and 6.6 A. Because the channel height CH is small compared to the channel width W1, areas of the vertical channel surfaces 208xzs are smaller than areas of the horizontal channel surfaces 208xys, roughness reducing effect from the vertical channel surfaces 208xzs has less than roughness reducing effect form the horizontal channel surfaces 208xys.

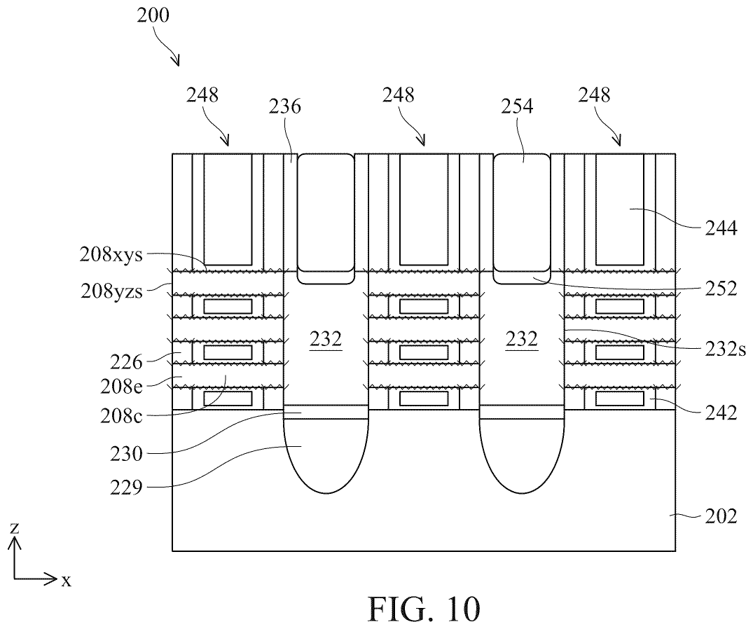

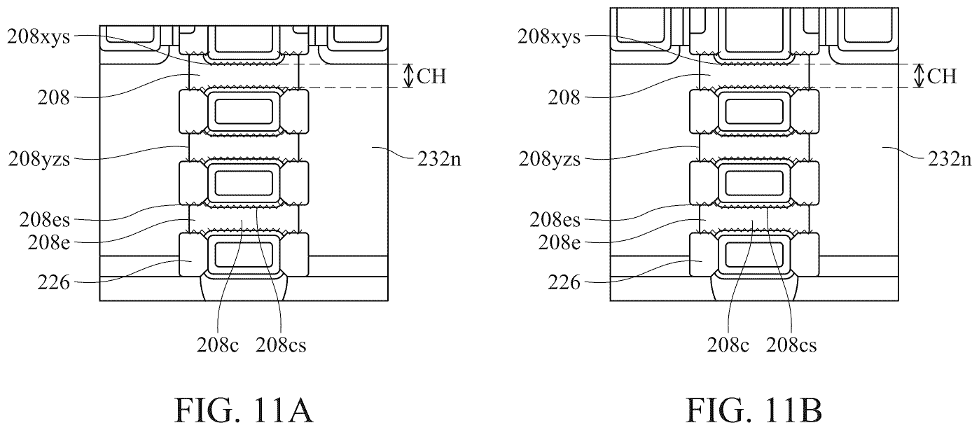

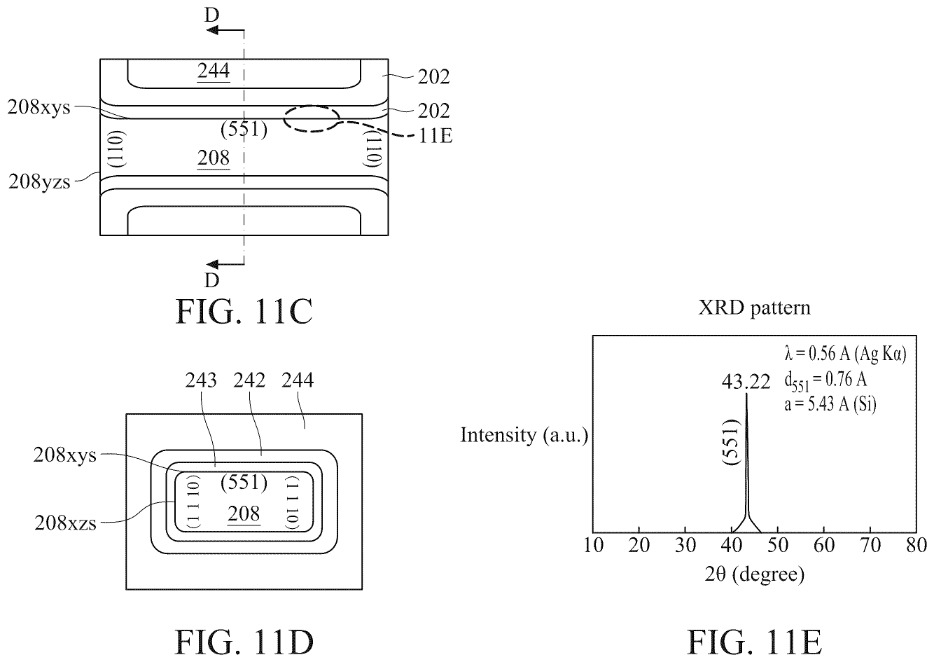

At operation 122, replacement gate structures 248 are formed over the central portions 208c of the semiconductor layers 208 and filled in the gate cavities 240, as shown in FIG. 10. The replacement gate structures 248 includes a gate dielectric layer 242 and a gate electrode layer 244. In some embodiments, an interfacial layer 243 (shown in FIGS. 11A-11D) may be formed on the semiconductor layers 208 prior to formation of the gate dielectric layer 242.

The gate dielectric layer 242 is formed on exposed surfaces in the gate cavities. The gate dielectric layer 242 may have different composition and dimensions for N-type devices and P-type devices and are formed separately using patterned mask layers and different deposition recipes. The gate dielectric layer 242 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTIO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 242 may be formed by CVD, ALD or any suitable method.

The gate electrode layer 244 is formed on the gate dielectric layer 242 to fill the gate cavities. The gate electrode layer 244 may include one or more layers of conductive material, such as tungsten, aluminum, copper, titanium, tantalum, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the gate electrode layer 244 may be formed by CVD, ALD, electro-plating, or other suitable method. In some embodiments, the gate electrode layer 244 may include different conductive materials and formed in different processes. Alternatively, the gate electrode layer 244 may include the same conductive material and formed in the same process. After the formation of the gate electrode layer 244, a planarization process, such as a CMP process, is performed to remove excess deposition of the gate electrode material and expose the top surface of the ILD layer 238.

Subsequently source/drain contact features 254 are formed. Contact holes may be formed through the ILD layer 238 and the CESL 236 to expose the epitaxial source/drain regions 232, and subsequently filled with a conductive material. Suitable photolithographic and etching techniques are used to form the contact holes through various layers. After the formation of the contact holes, a silicide layer 252 is selectively formed over surfaces of the epitaxial source/drain regions 232 exposed by the contact holes. The silicide layer 252 may be formed by depositing a metal source layer to cover exposed surfaces including the exposed surfaces of the epitaxial source/drain regions 232 and performing a rapid thermal annealing process. In some embodiments, the metal source layer includes a metal layer selected from W, Co, Ni, Ti, Mo, and Ta, or a metal nitride layer selected from tungsten nitride, cobalt nitride, nickel nitride, titanium nitride, molybdenum nitride, and tantalum nitride. After the formation of the metal source layer, a rapid thermal anneal process is performed. During the rapid anneal process, the portion of the metal source layer over the epitaxial source/drain regions 232 reacts with silicon in the epitaxial source/drain regions 232 to form the silicide layer 252. Unreacted portion of the metal source layer is then removed. In some embodiments, the silicide layer 252 may include one or more of WSi, CoSi, NiSi, TiSi, MoSi, and TaSi.

After formation of the silicide layer 252, a conductive material is deposited to fill contact holes and form the source/drain contact features 254. Optionally, a barrier layer, not shown, may be formed in the contact holes prior to forming the source/drain contact features 254. In some embodiments, the conductive material layer for the gate contact may be formed by CVD, PVD, plating, ALD, or other suitable technique. In some embodiments, the conductive material for the source/drain contact features 254 includes TiN, TaN, Ta, Ti, Hf, Zr, Ni, W, Co, Cu, Ag, Al, Zn, Ca, Au, Mg, Mo, Cr, or the like. Subsequently, a CMP process is performed to remove a portion of the conductive material layer above a top surface of the ILD layer 238.

Embodiments of the present disclosure provide a solution to improve hole mobility without sacrificing electron mobility while scaling down. FIGS. 11A-11E illustrate gate areas of GAA devices according to embodiments of the present disclosure. FIG. 11A is a schematic enlarged view of an NFET device according to the present disclosure. FIG. 11B is a schematic enlarged view of a PFET device according to the present disclosure. FIG. 11C is an enlarged view of the NFET device of FIG. 11A showing details around one channel. FIG. 11D is a schematical cross section of FIG. 11C along the D-D line. As shown in FIGS. 11A and 11B, the channel regions of the NFET device and the PFET device have similar channel composition. In some embodiments, both the NFET device and the PFET device have semiconductor layers 208 as nanosheet channels. The semiconductor layers 208 (or channels) are formed from epitaxial silicon, having horizontal channel surfaces 208xys on (551) plane along <110> direction, along <110> direction, and end channel surfaces 208yzs on (110) plane along <110> direction. In some embodiments, source/drain region 232n for the NFET device are formed from SiP. In some embodiments, source/drain region 232p for the PFET device are formed from SiGe.

In some embodiments, the center portion 208c of the semiconductor layers 208 (or channel layer) and the end portions 208e of the semiconductor layers 208 have different surface roughness. The center portion 208c is smoother or has a lower roughness than the end portions 208e.

FIG. 11E is a XRD pattern (x-ray diffraction pattern) of the interface in the area 11E in FIG. 11D. The XRD pattern indicates the (551) silicon surface at the horizontal channel surface 208xys can clear observed.

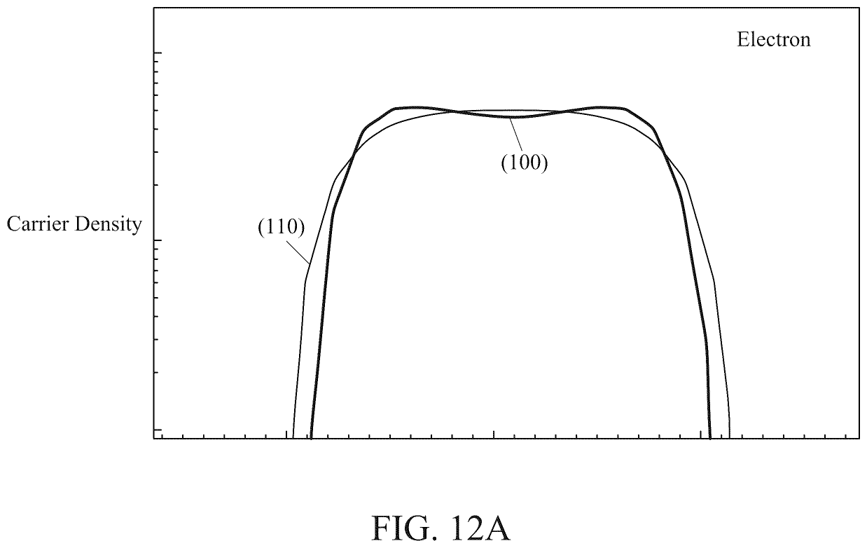

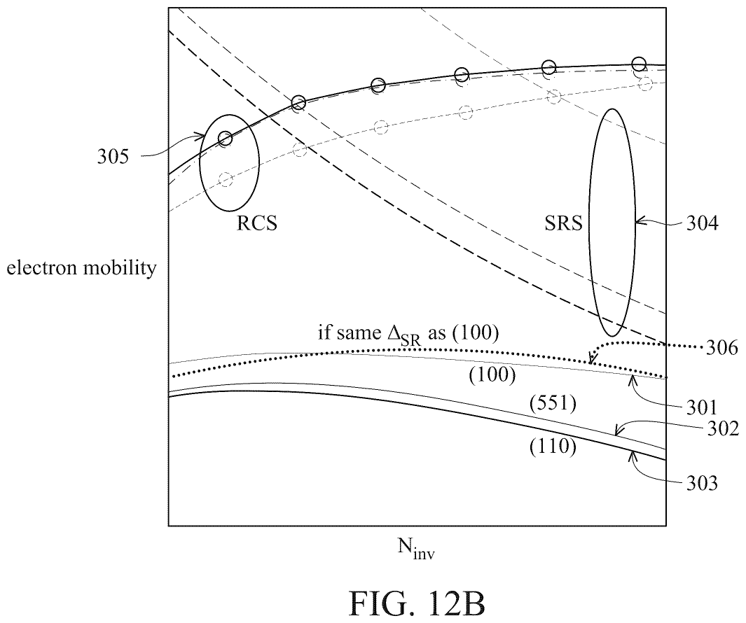

FIG. 12A is a chart shows the electron mobility for (110) channel surface and (100) surface channel along a channel height. As shown in FIG. 12A, the electron carriers of (110) channel surface are far away from the interfaces, such as the interface between the semiconductor layer 208 and the interfacial layer 243, than the electron carriers at the interfaces of (100) channel surface. In other words, electron carriers of (110) channel surfaces are more concentrated at the center of the channel layer or semiconductor layer 208 or channel sheet than electron carriers of (100) channel surfaces. The (110) channel surfaces are less sensitive to surrounding gate stack (i.e., RCS factor), but are more sensitive to surface roughness (i.e., SRS factor) than (100) channel surfaces.

FIG. 12B is a chart showing that after a roughness treatment according to the present disclosure, the (551)/<110> channel surface having similar electron mobility to the (100) channel surface. In FIG. 12B, curves 301, 302, 303 represent electron mobility of (110) channel surface, (551) channel surface, and (100) channel surface respectively. The (100) channel surface has the highest electron mobility. Curve group 304 demonstrates the SRS factor of (100), (551), and (110) surfaces to the electron mobility. Curve group 305 demonstrates the RCS factor of (100), (551), and (110) surfaces to the electron mobility. Curve 306 presents electron mobility of (551) surface after roughness treatment according to embodiments of the present disclosure. Curve 306 shows that (551)/<110> channel surface has similar electron mobility to the (100) channel surface.

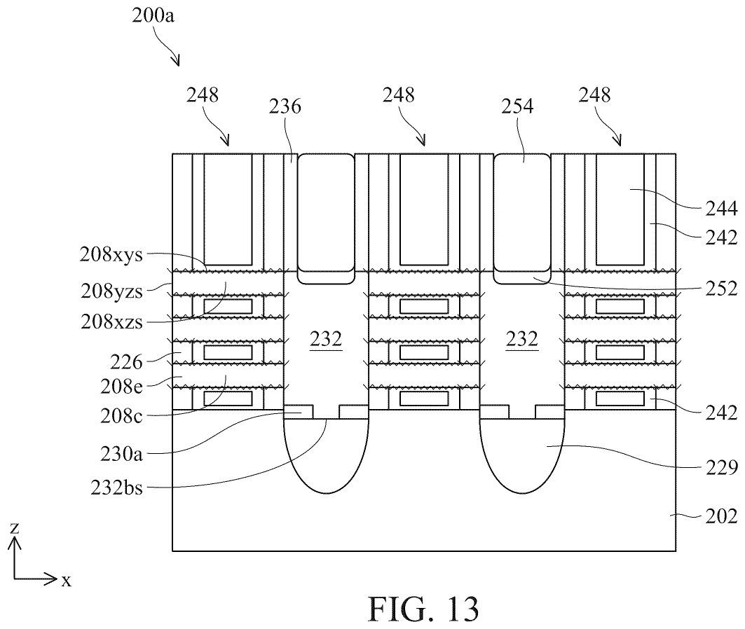

FIG. 13 is a schematic cross sectional view of a semiconductor device 200a according to the present disclosure. The semiconductor device 200a is similar to the semiconductor device 200 except that the semiconductor device 200a includes a partial bottom isolation layer 230a. Therefore, a bottom portion of epitaxial source/drain regions 232a is grown from the bottom epitaxial layer 229, which has a (551) surface. As a result, a portion of a bottom surface 232abs of the epitaxial source/drain region 232a has a (551) surface.

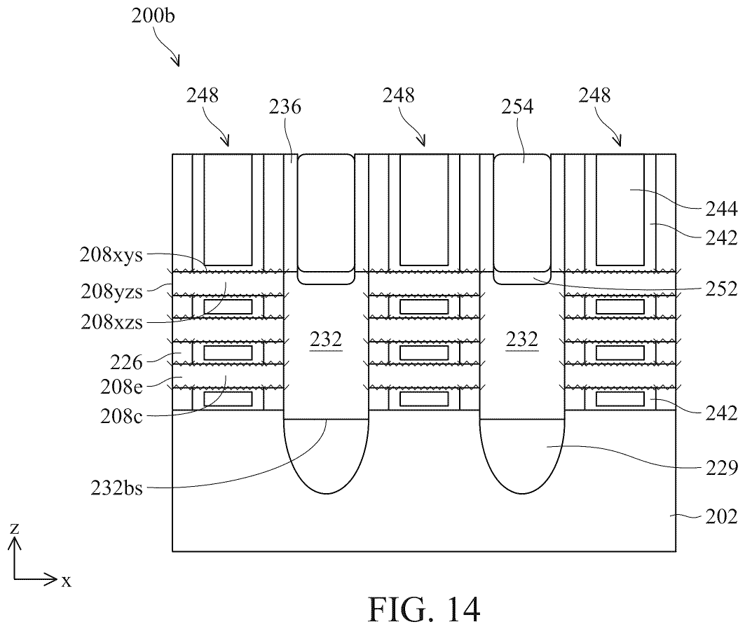

FIG. 14 is a schematic cross sectional view of a semiconductor device 200b according to the present disclosure. The semiconductor device 200b is similar to the semiconductor device 200, 200a except that the semiconductor device 200b does not include any bottom isolation layer. Therefore, epitaxial source/drain regions 232b is also grown from the bottom epitaxial layer 229, which has a (551) surface. As a result, a bottom surface 232bbs of the epitaxial source/drain region 232b has a (551) surface.

Various embodiments or examples described herein offer multiple advantages over the state-of-art technology. By selecting (551)/<110> substrate as starting material, embodiments of the present disclosure enable channel height scaling with improved hole mobility and without sacrificing electron mobility.

Some embodiments of the present provide a semiconductor device, comprising: a first source/drain region; a second source/drain region; two or more semiconductor layers disposed between and coupled with the first and second source/drain regions, wherein the two or more semiconductor layers are formed on a (551) plane; and a gate structure wrapped around the two or more semiconductor layers.

Some embodiments of the present disclosure provide a semiconductor device, comprising: two or more semiconductor layers, wherein each of the two or more semiconductor layers includes a first end portion, a second end portion, a center portion connecting the first and second end portions, the first end portion has a first surface roughness, the center portion has a second surface roughness different from the first surface roughness; a gate structure wrapped around the center portions of the two or more semiconductor layers; a first source/drain region disposed on the first end portions of the two or more semiconductor layers; and a second source/drain region disposed on the second end portions of the two or more semiconductor layers.

Some embodiments of the present disclosure provide a method for forming a semiconductor device, comprising: selecting a substrate having a top surface with a (551) surface orientation, epitaxially growing a semiconductor stack from the top surface of the substrate, wherein the semiconductor stack comprises two or more first semiconductor layers and two or more second semiconductor layer, and the two or more first semiconductor layers are alternatively stacked with the two or more second semiconductor layers; forming a fin structure from the semiconductor stack and the substrate; forming a sacrificial gate structure over the fin structure; etching back the fin structure along sidewalls of the sacrificial gate structure; epitaxially growing source/drain regions from the two or more second semiconductor layers; depositing a contact etch stop layer (CESL) over the source/drain regions; depositing an interlayer dielectric (ILD) layer over the CESL; removing the sacrificial gate structure to expose the fin structure; removing two or more first semiconductor layers; and forming a replacement gate structure around the two or more second semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first source/drain region;
a second source/drain region;
two or more semiconductor layers disposed between and coupled with the first and second source/drain regions, wherein the two or more semiconductor layers are formed on a (551) plane; and
a gate structure wrapped around the two or more semiconductor layers.

2. The semiconductor device of claim 1, wherein each of the two or more semiconductor layers has a <110> crystalline direction extending along a direction from the first source/drain region to the second source/drain region.

3. The semiconductor device of claim 2, wherein each of the two or more semiconductor layers includes:
a top surface;
a bottom surface opposing the top surface; and
a vertical surface connecting the top surface to the bottom surface, wherein the vertical surface extends from the first source/drain region and the second source/drain region, wherein the top surface has a (551) surface orientation, and the vertical surface has a (110) surface orientation.

4. The semiconductor device of claim 3, wherein a distance between the top surface and the bottom surface is in a range between about 2 nm and about 10 nm.

5. The semiconductor device of claim 3, wherein each of the two or more semiconductor layers further includes:
a first end surface connecting the top surface and the bottom surface, wherein the first end surface is in contact with a side wall of the first source/drain region, and the first end surface has a (110) surface orientation.

6. The semiconductor device of claim 5, wherein each of two or more semiconductor layers comprises a first end portion adjacent the first end surface, and a center portion in contact with the gate structure, the first end portion has a first surface roughness, the center portion has a second surface roughness different from the first surface roughness.

7. The semiconductor device of claim 6, wherein the first surface roughness is greater than the second surface roughness.

8. A semiconductor device, comprising:
two or more semiconductor layers, wherein each of the two or more semiconductor layers includes a first end portion, a second end portion, a center portion connecting the first and second end portions, the first end portion has a first surface roughness, the center portion has a second surface roughness different from the first surface roughness;
a gate structure wrapped around the center portions of the two or more semiconductor layers;
a first source/drain region disposed on the first end portions of the two or more semiconductor layers; and
a second source/drain region disposed on the second end portions of the two or more semiconductor layers.

9. The semiconductor device of claim 8, wherein the first surface roughness is greater than the second surface roughness.

10. The semiconductor device of claim 9, wherein each of two or more semiconductor layers include a horizontal channel surface with a (551) surface orientation.

11. The semiconductor device of claim 10, wherein the horizontal channel surface has a <110> crystalline direction extending from the first source/drain region and the second source/drain region.

12. The semiconductor device of claim 11, wherein each of two or more semiconductor layers include a vertical channel surface with a (110) surface orientation.

13. The semiconductor device of claim 12, wherein the vertical channel surface has a third surface roughness greater than the second surface roughness.

14. The semiconductor device of claim 10, wherein the first source/drain region has a bottom surface formed on a (551) surface orientation.

15. A method for forming a semiconductor device, comprising:
selecting a substrate having a top surface with a (551) surface orientation;
epitaxially growing a semiconductor stack from the top surface of the substrate, wherein the semiconductor stack comprises two or more first semiconductor layers and two or more second semiconductor layer, and the two or more first semiconductor layers are alternatively stacked with the two or more second semiconductor layers;
forming a fin structure from the semiconductor stack and the substrate;
forming a sacrificial gate structure over the fin structure;
etching back the fin structure along sidewalls of the sacrificial gate structure;
epitaxially growing source/drain regions from the two or more second semiconductor layers;
depositing a contact etch stop layer (CESL) over the source/drain regions;
depositing an interlayer dielectric (ILD) layer over the CESL;
removing the sacrificial gate structure to expose the fin structure;
removing two or more first semiconductor layers; and
forming a replacement gate structure around the two or more second semiconductor layers.

16. The method of claim 15, wherein forming the fin structure comprises:
forming the fin structure along a <110> crystalline direction.

17. The method of claim 16, further comprising:
prior to forming the replacement gate structure, performing a roughness treatment process to reduce a surface roughness of the second semiconductor layers.

18. The method of claim 17, wherein performing the roughness treatment process comprises treating the two or more second semiconductor layers with a plasma.

19. The method of claim 18, wherein the plasma comprises H radicals.

20. The method of claim 15, wherein epitaxial growing the source/drain regions comprises growing a bottom surface from a (551) surface of the substrate.
